(19) United States
(12) Patent Application Publication
(10) Pub. No.: US 2025/0253189 A1
(43) Pub. Date: Aug. 7, 2025

(54) SEMICONDUCTOR DEVICE STRUCTURE AND METHOD OF FABRICATING SAME

(71) Applicant: Taiwan Semiconductor Manufacturing Company,LTD., Hsinchu (TW)

(72) Inventors: Jheng-Hong Jiang, Hsinchu (TW); Shing-Huang Wu, Hsinchu (TW); Chia-Wei Liu, Zhubei (TW)

(21) Appl. No.: 18/430,868

(22) Filed: Feb. 2, 2024

(51) Int. Cl. H01L 21/768; H01L 21/306; H01L 23/522

(52) U.S. Cl. CPC H01L 21/76831; H01L 21/30625; H01L 21/76849; H01L 21/76877; H01L 23/5226

(57) ABSTRACT

A semiconductor device structure, and fabrication method that includes a first dielectric component and resonator components positioned within the first dielectric component. The semiconductor device structure further includes a second dielectric component that is positioned on the first dielectric component. A capping metal layer is positioned on the second dielectric component. The capping metal layer includes one or more capping metal VIAs that extend through the second dielectric component to one of the resonator components.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer the pattern to a layer below the photoresist. This process is repeated multiple times with different patterns to build different layers on the wafer substrate and make a useful device. This process is used in the formation of a variety of devices, including fabrication of light emitting diodes and corresponding displays. Traditional formation of such devices utilizes a stepped or staggered cathode or capping metal layer, which causes weaknesses (e.g., lack of adhesion, lack of uniformity, interface stress, etc.) in the upper layers of the device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of the semiconductor device structure, in accordance with some embodiments.

FIG. 2 is a simplified cross-sectional view of the semiconductor device structure in accordance with some embodiments.

FIGS. 3A-3X are cross-sectional views of varying stages of fabrication of semiconductor device structure in accordance with some embodiments.

FIGS. 4A-4B are respective top and cross-sectional views of a semiconductor device structure in accordance with a first embodiment.

FIGS. 5A-5B are respective top and cross-sectional views of a semiconductor device structure in accordance with a second embodiment.

FIGS. 6A-6B are respective top and cross-sectional views of a semiconductor device structure in accordance with a third embodiment.

FIG. 7 is a top view of a semiconductor device structure in accordance with a fourth embodiment.

FIG. 8 is a top view of a semiconductor device structure in accordance with a fifth embodiment.

FIGS. 9A-9B are a flowchart illustrating a method for fabricating a semiconductor device structure in accordance with one embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to structures which are made up of different layers. When the terms “on” or “upon” or “over” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them.

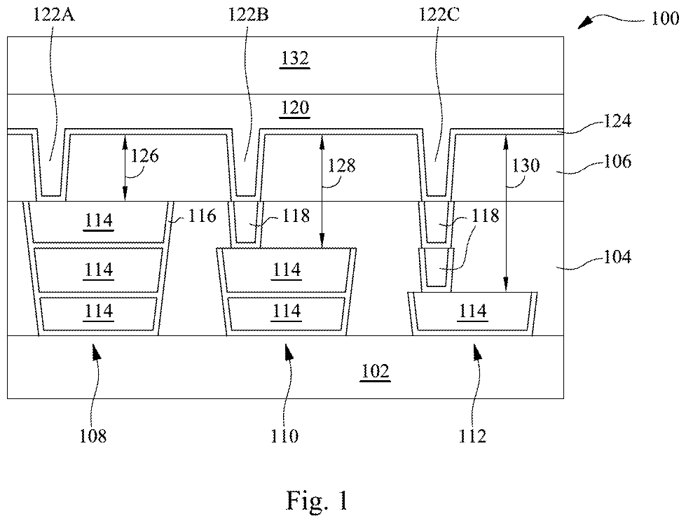

Turning now to FIG. 1, there is shown a cross-sectional view of semiconductor device structure 100 fabricated in accordance with one embodiment of the subject application. As illustrated in FIG. 1, the semiconductor device structure 100 includes a base structure or layer 102. In accordance with varying embodiments, the base structure or layer 102 may correspond to any of a variety of layers of BEOL processing, BEOL metal routing, devices, components, FEOL device(s) (e.g., transistor), etc. The semiconductor device structure 100 further includes a first dielectric component 104 positioned on the base layer or structure 102, as shown in FIG. 1. The first dielectric component 104 may comprise, for example and without limitation, one or more layers of undoped silicate glass (USG), silicon nitride (SIN), phosphosilicate glass (PSG), borophosphosilicate glass (BPSG), fluorosilicate glass (FSG), low-k dielectric material (LK), extreme low-k dielectric material (ELK), Black Diamon (BD) low-k dielectric material, or the like. It will be appreciated that other suitable silicate glasses or materials providing similar optic properties and/or insulative properties may be used in other embodiments.

In accordance with some embodiments, the first dielectric component 104 may be implemented with a thickness in the range of about 100 angstroms to 500,000 angstroms (100A to 500kA).

The semiconductor device structure 100 also includes a second dielectric component 106 formed or positioned on the first dielectric component 104, as shown in FIG. 1. The second dielectric component 106 may comprise, for example and without limitation, one or more layers of USG, SiN, PSG, BPSG, FSG, LK, ELK, BD, or the like. It will be appreciated that other suitable silicate glasses or materials providing similar optic properties and/or insulative properties may be used in other embodiments. In accordance with some embodiments, second dielectric component 106 may be implemented with a thickness in the range of about 100A to 500kA.

Formed within the first dielectric layer 104 are a first resonator component (R-1) 108, a second resonator component (R-2) 110, and a third resonator component (R-3) 112. The three resonator components 108-112 together form a pixel, as will be understood in the art. In accordance with some embodiments, each resonator component 108-112 corresponds to a different optical lighting path. That is, the first resonator component (R-1) 108 corresponding to a red pixel component, the second resonator component (R-2) 110 corresponding to a green pixel component, and the third resonator component (R-3) 112 corresponding to a blue pixel component. Each of the first, second and third resonator components 108-112 comprise one or more layers of a resonator metal 114, as shown in FIG. 1. It will be appreciated that other embodiments of the semiconductor device structure 100 are contemplated herein, and the number of resonators 108-112 is intended as a nonlimiting example thereof. In such other embodiments, the semiconductor device structure 100 may be implemented with two, four, five, six, etc., resonators, as will be appreciated.

The resonator metal 114 of the resonator components 108-112 may be implemented as, for example and without limitation, aluminum copper (AICu), aluminum silicon copper (AISiCu), aluminum silicon (AISi), tungsten (W), gold (Ag), copper (Cu), or the like. It will be appreciated that other suitable metals or metal-alloy materials providing similar conductive properties may be used in other embodiments. In accordance with some embodiments, the resonator metal 114 may be implemented with a thickness in the range of about 100A to 500kA.

The semiconductor device structure 100 also includes a resonator metal glue layer 116, positioned on and around layers of the resonator components 108-112, as shown in FIG. 1. The resonator metal glue layer 116 may include, for example and without limitation, titanium nitride (TiN), tantalum nitride (TaN), tungsten (W), titanium (Ti), tantalum (Ta), or the like. In accordance with some embodiments, the resonator metal glue layer 116 may be implemented with a thickness in the range of about 100A to 10kA. Depending upon the number of layers of resonator metal 114 of each resonator component 108-112, resonator VIAs 118 may be included to couple the respective resonator component 108-110 to a capping metal VIA 122A-122C, as discussed below.

As shown in FIG. 1, each of the aforementioned resonator VIAs 118 are encapsulated, surrounded, etc., by the resonator metal glue layer 116. As shown in FIG. 1, the first resonator component (R-1) 108 includes three layers of resonator metal 114, the second resonator component (R-2) 110 includes two layers of resonator metal 114, and the third resonator component (R-3) 112 includes one layer of resonator metal 114. Depending upon the fabrication process, it will be appreciated that the number of layers described above are intended as non-limiting and each “layer 114” may consist of multiple layers of resonator metal material.

As illustrated in FIG. 1, a capping metal layer 120 is formed or positioned above the second dielectric component 106. In accordance with some embodiments, the capping metal layer 120 may be implemented as, for example and without limitation, AICu, AISiCu, AISi, W, ITO, Cu, or the like. It will be appreciated that other suitable metals or metal-alloy materials providing similar conductive properties may be used in other embodiments. In accordance with some embodiments, the capping metal layer 120 may be implemented with a thickness in the range of about 100A to 500kA. It will be appreciated that in some embodiments, the capping metal layer 120 may correspond to a cathode layer, depending upon the device for which the structure 100 is intended. Extending downward from the capping metal layer 120 are a first capping metal VIA 122A contacting the first resonator component (R-1) 108, a second capping metal VIA 122B contacting the second resonator component (R-2) 110, and a third capping metal VIA 122C contacting the third resonator component (R-3) 112. It will be appreciated that the metal capping VIAs 122A-122C may comprise the same material as that of the metal capping layer 120.

As shown in FIG. 1, each resonator component 108-110 is positioned a preselected distance from the capping metal layer 120, in accordance with the number of resonator metal layers 114 used therein. Accordingly, the first resonator component (R-1) 108 is positioned a first resonator depth (D1) 126 below the capping metal layer 120. Similarly, the second resonator component (R-2) 110 is positioned a second resonator depth (D2) 128 below the capping metal layer 120, and the third resonator component (R-3) 112 is positioned a third resonator depth (D3) 130 below the capping metal layer 120. In such embodiments, it will be appreciated that D1<D2<D3. In other embodiments, the relationship between depths may change depending upon the location or position of the resonator components 108-112 within the semiconductor device structure 100.

FIG. 1 further depicts a luminous device 132 operatively coupled to the semiconductor device structure 100. As will be appreciated, the luminous device 132 is intended solely as one example device capable of attachment to the capping metal layer 120. That is, the skilled artisan will appreciate that the semiconductor device structure 100 depicted in FIG. 1 may be fabricated at any point of the BEOL process, i.e., it may be interposed between various components on a chip or wafer, and/or, as shown in FIG. 1, be used to allow subsequent bonding, coupling, attachment, etc., of a separate device. Accordingly, the luminous device 132 referenced in FIG. 1 may be an OLED array, a lighting layer, a transistor layer, a memory layer, a portion of RAM or logic, etc., and the subject application is not limited to the aforementioned luminous device 132.

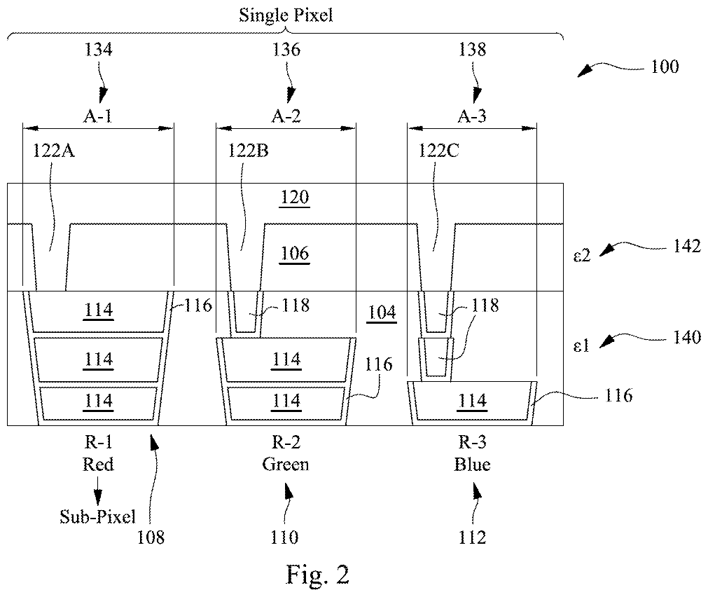

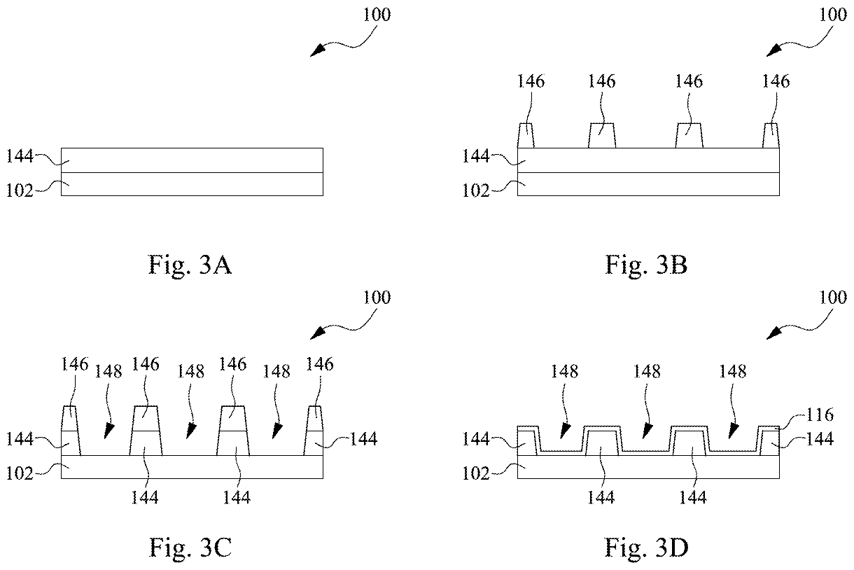

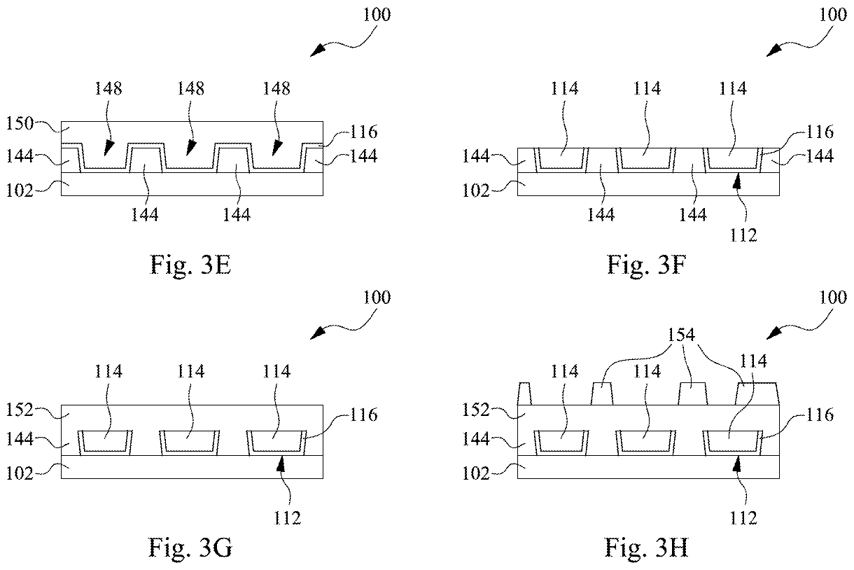

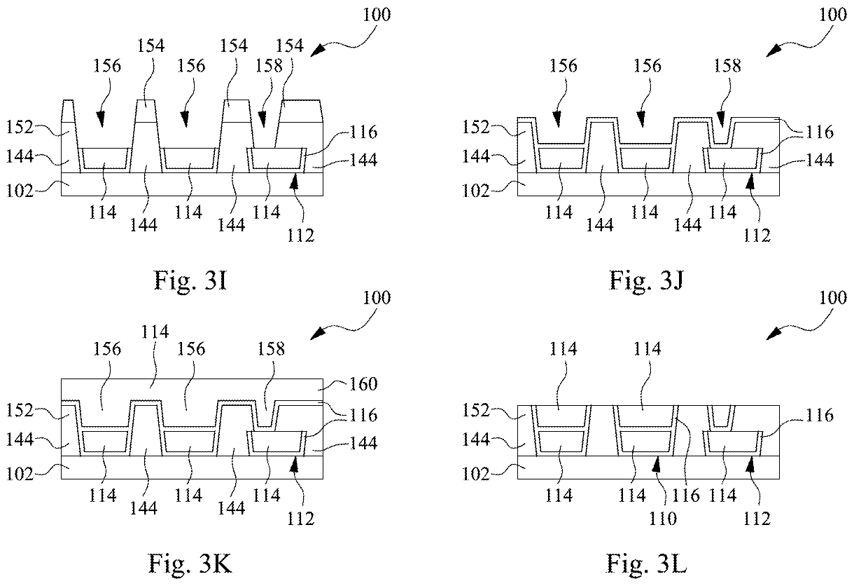

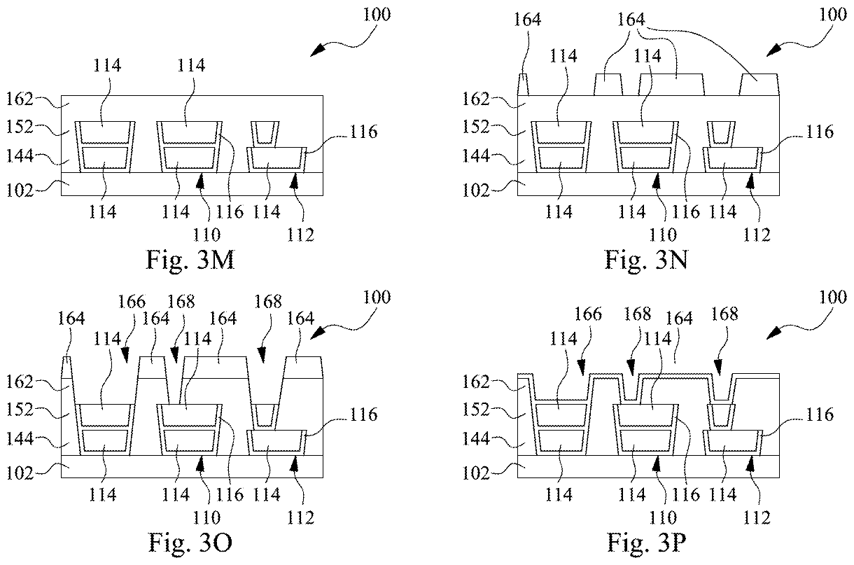

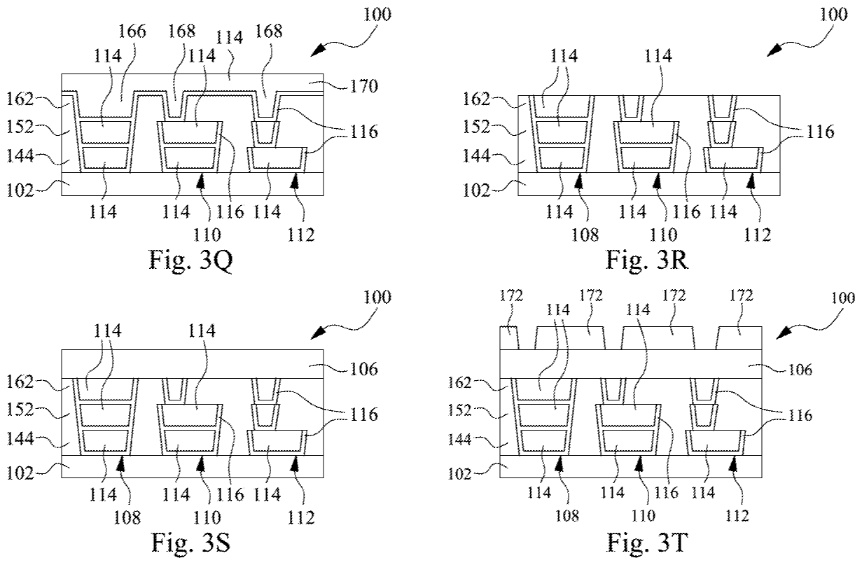

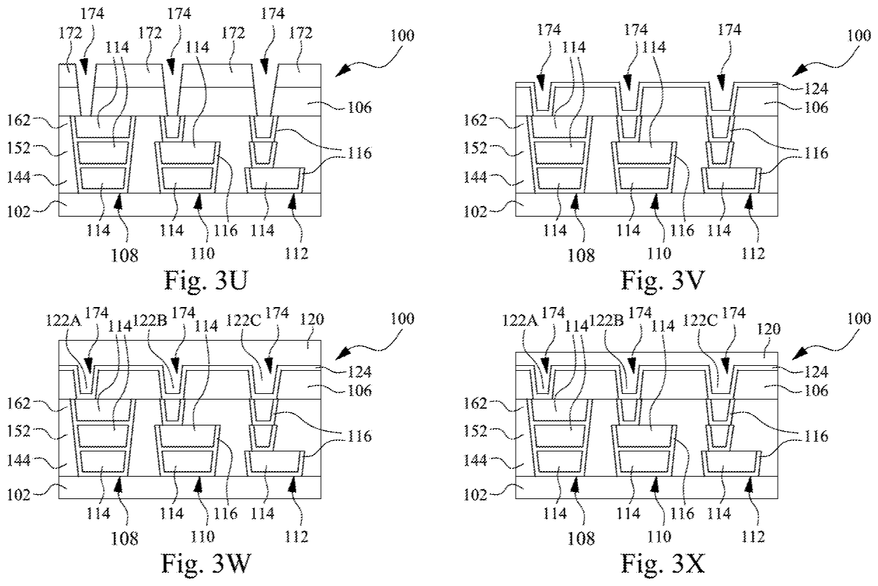

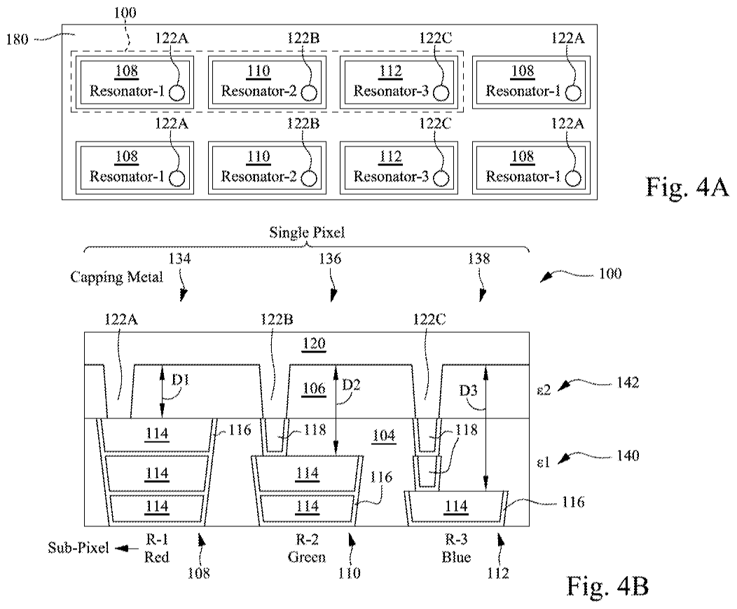

Referring now to FIG. 2, there is shown a simplified view of the semiconductor device structure 100 of FIG. 1. As illustrated in FIG. 2, the first resonator component (R-1) 108 corresponds to the red sub-pixel of the device 100, and includes a first resonator area (A-1) 134. In some embodiments, the first resonator area (A-1) 134 may have a width in the ranged of about 10 nm to 500 μm. The second resonator component (R-2) 110 is depicted as corresponding to the green sub-pixel of the semiconductor device structure 100, and includes a second resonator area (A-2) 136. In some embodiments, the second resonator area (A-2) 136 may have a width in the ranged of about 10 nm to 500 um. Similarly, the third resonator component (R-3) 112 is shown as corresponding to the blue sub-pixel of the semiconductor device structure 100 and includes a third resonator area (A-3) 138. In some embodiments, the third resonator area (A-3) 138 may have a width in the ranged of about 10 nm to 500 um. Further, the pixel represented by the semiconductor device structure 100 of FIG. 2 illustrates the first dielectric component 104 having a first dielectric material constant (ε1) 140 and the second dielectric component 106 having a second dielectric material constant (ε2) 142. In some embodiments contemplated herein, the resonator components 108-112 may have areas (134-138) implemented in varying ratios to each other. That is, A-1:A-2:A-3 may correspond to a 1:1:1 ratio, i.e., each sub-pixel or resonator component 108-112 has the same area. In other embodiments, the ratio of areas A-1:A-2:A-3 may vary, i.e., A-1 has an area of “x”, A-2 has area of “y” and A-3 has an area of “z”, such that the ratio of areas 134-138 of respective resonator components 108-112 is x:y:z. With respect to the first and second dielectric components 104 and 106, the dielectric constants (ε1) 140 and (ε2) 142 may be the same (ε1=ε2) or different (ε1≠ε2). That is, in some embodiments, the first dielectric component 104 and the second dielectric component 106 are the same material (or different materials with the same dielectric constant), or different materials (with different dielectric constants). FIGS. 4A-8 provide additional views of changes in areas in accordance with alternate embodiments. Formation of the various components described above with respect to FIGS. 1 and 2 are discussed in detail below with respect to FIGS. 3A-3X.

FIGS. 3A-3X provide cross-sectional views of varying stages of fabrication of semiconductor device structure 100 in accordance with some embodiments. The patterning of a layer may employ any suitable patterning technique such as a photolithographic patterning technique using deposition of a photoresist layer and selective exposure via a photomask to visible light, ultraviolet light, deep ultraviolet light (i.e., DUV lithography), extreme ultraviolet light (i.e. EUV lithography), or so forth, followed by development of the exposed photoresist and subsequent etching, deposition or other process steps laterally delineated by the developed photoresist. In other embodiments, patterning of an electron-sensitive resist layer may be by way of electron beam exposure (electron beam lithography, i.e., e-beam lithography). The skilled artisan will appreciate that the foregoing are merely illustrative examples.

Referring now to FIG. 3A, there is shown an initial stage of fabrication of the semiconductor device structure 100 in accordance with some embodiments. As depicted in FIG. 3A, a first layer 144 of the first dielectric component 104 is formed on a base structure or layer 102. In accordance with some embodiments, the first layer 144 may be implemented as, for example and without limitation, USG, SiN, PSG, BPSG, FSG, LK, ELK, BD, or the like. It will be appreciated that other suitable silicate glasses or materials providing similar optic properties and/or insulative properties may be used in other embodiments. In accordance with some embodiments, formation of the first layer 144 of the first dielectric component 104 may be accomplished via any suitable deposition or layer processes, including, for example and without limitation, deposited by, for example, chemical vapor deposition (CVD), physical vapor deposition (PVD), atomic layer deposition (ALD), sputtering, another deposition process, or any suitable combination thereof. In some embodiments, chemical-mechanical polishing (CMP) may be performed after deposition of the first layer 144, resulting in the planar surface shown in FIG. 3A.

In FIG. 3B, a photoresist 146 is deposited and patterned on the first layer 144 of the first dielectric component 104. In some embodiments, the photoresist 146 is applied to the first layer 144 of the first dielectric component 104, after which portions of the photoresist 146 are developed by exposure from a suitable light source to form a pattern thereon. The unexposed portions are then removed, resulting in the patterned photoresist 146 shown in FIG. 3B.

Etching is then performed in accordance with the patterned photoresist 146, removing unprotected portions of the first layer 144 of the first dielectric component 104, and forming resonator cavities 148 in the first layer 144 of the first dielectric component 104 as shown in FIG. 3C. That is, portions of the first layer 144 of the dielectric component 104 unprotected by the aforementioned photoresist 146 are removed, resulting in the resonator cavities 148. Suitable removal processes include, for example and without limitation, an etching process implemented as a dry etching process, a RIE process, a wet etching process, some other etching process, or a combination of the foregoing. FIG. 3C provides an illustration of a stage of fabrication of the semiconductor device structure 100 after formation of the resonator cavities 148.

In FIG. 3D, a resonator metal glue layer 116 is shown deposited on the first layer 144 of the first dielectric component 104 and on the surfaces of the resonator cavities 148. The resonator metal glue layer 116 may include, for example and without limitation, titanium nitride (TiN), tantalum nitride (TaN), tungsten (W), titanium (Ti), tantalum (Ta), or the like. In accordance with some embodiments, the resonator metal glue layer 116 may be implemented with a thickness in the range of about 100A to 10kA. In accordance with some embodiments, formation of the resonator metal glue layer 116 may be accomplished via any suitable deposition or layer processes, including, for example and without limitation, deposited by, for example, chemical vapor deposition (CVD), physical vapor deposition (PVD), atomic layer deposition (ALD), sputtering, another deposition process, or any suitable combination thereof.

A first layer 150 of resonator metal 114 is then deposited on the resonator metal glue layer 116 of the semiconductor device structure 100, filling the resonator cavities 148. FIG. 3E provides an illustrative example of the deposition of the first layer 150 of resonator metal 114 on the semiconductor device 100. In accordance with some embodiments, the resonator metal material 114 may comprise, for example and without limitation, W, Cu, Al, AICu, AISiCu, AISi, or the like. It will be appreciated that other suitable metals or metal-alloy materials providing similar conductive properties may be used in other embodiments. Suitable deposition methods for the resonator metal material 114 may include, for example and without limitation, chemical vapor deposition (CVD), physical vapor deposition (PVD), atomic layer deposition (ALD), electrochemical plating (ECP), sputtering, another deposition process, or any suitable combination thereof. Thereafter, as shown in FIG. 3F, chemical-mechanical polishing (CMP) is performed on the semiconductor device structure 100 to remove portions of the first layer 150 of the resonator metal material 114 and the resonator metal glue layer 116. It will be appreciated that the required resonator metal material 114 of the third resonator component (R-3) 112 has thus been formed, while additional resonator metal material 114 remains to be formed for the remaining resonator components (R-1) 108 and (R-2) 110.

As shown in FIG. 3G, a second layer 152 of the first dielectric component 104 is formed on first layer 144 and the remaining first layer 150 of the resonator metal material 114. In accordance with some embodiments, the second layer 152 may be implemented as, for example and without limitation, USG, SiN, PSG, BPSG, FSG, LK, ELK, BD, or the like. It will be appreciated that other suitable silicate glasses or materials providing similar optic properties and/or insulative properties may be used in other embodiments. In accordance with some embodiments, formation of the second layer 152 of the first dielectric component 104 may be accomplished via any suitable deposition or layer processes, including, for example and without limitation, deposited by, for example, chemical vapor deposition (CVD), physical vapor deposition (PVD), atomic layer deposition (ALD), sputtering, another deposition process, or any suitable combination thereof. In some embodiments, chemical-mechanical polishing (CMP) may be performed after deposition of the second layer 152, resulting in the planar surface shown in FIG. 3G.

A photoresist 154 is then deposited and patterned on the second layer 152 of the first dielectric component 104, as shown in FIG. 3H. In some embodiments, the photoresist 154 is applied to the second layer 152 of the first dielectric component 104, after which portions of the photoresist 154 are developed by exposure from a suitable light source to form a pattern thereon. The unexposed portions are then removed, resulting in the patterned photoresist 154 shown in FIG. 3H. Etching is then performed in accordance with the patterned photoresist 154, removing unprotected portions of the second layer 152 of the first dielectric component 104, and forming second resonator cavities 156 and a first resonator VIA cavity 158 in the second layer 152 of the first dielectric component 104 as shown in FIG. 3I. That is, portions of the second layer 152 of the dielectric component 104 unprotected by the aforementioned photoresist 154 are removed, resulting in the second resonator cavities 156 and the first resonator VIA cavity 158. Suitable removal processes include, for example and without limitation, an etching process implemented as a dry etching process, a RIE process, a wet etching process, some other etching process, or a combination of the foregoing.

In FIG. 3J, a resonator metal glue layer 116 is shown deposited, after removing the photoresist 154, on the second layer 152 of the first dielectric component 104 and on the surfaces of the second resonator cavities 156 and the first resonator VIA cavity 158. As described above, the resonator metal glue layer 116 may include, for example and without limitation, TiN, TaN, W, Ti, Ta, or the like, and may be implemented with a thickness in the range of about 100A to 10kA. Formation of the resonator metal glue layer 116 may be accomplished via any suitable deposition or layer processes, including, for example and without limitation, deposited by, for example, CVD, PVD, ALD, sputtering, another deposition process, or any suitable combination thereof.

A second layer 160 of resonator metal 114 is then deposited on the resonator metal glue layer 116 of the semiconductor device structure 100, filling the second resonator cavities 156 and the first resonator VIA cavity 158. FIG. 3K provides an illustrative example of the deposition of the second layer 160 of resonator metal 114 on the semiconductor device 100. In accordance with some embodiments, the resonator metal material 114 may comprise, for example and without limitation, W, Cu, Al, AICu, AISiCu, AISi, or the like, which may be formed by CVD, PVD, ALD, ECP, sputtering, another deposition process, or any suitable combination thereof. It will be appreciated that other suitable metals or metal-alloy materials providing similar conductive properties may be used in other embodiments. Thereafter, as shown in FIG. 3L, chemical-mechanical polishing (CMP) is performed on the semiconductor device structure 100 to remove portions of the second layer 160 of the resonator metal material 114 and the resonator metal glue layer 116. It will be appreciated that the required resonator metal material 114 of the second resonator component (R-2) 110 has thus been formed, while additional resonator metal material 114 remains to be formed for the remaining resonator component (R-1) 108. That is, as shown in FIG. 3L, the second resonator component (R-2) 110 and the third resonator component (R-3) 112 are now formed in the first dielectric component 104.

A third layer 162 of the first dielectric component 104 is then formed on second layer 152 of the first dielectric component 104 and the remaining second layer 160 of the resonator metal material 114, as shown in FIG. 3M. In accordance with some embodiments, the third layer 162 may be implemented as, for example and without limitation, USG, SiN, PSG, BPSG, FSG, LK, ELK, BD, or the like, and formed by, for example and without limitation, any suitable deposition or layer processes, including, for example and without limitation, deposited by, for example, CVD, PVD, ALD, sputtering, another deposition process, or any suitable combination thereof. In accordance with other embodiments, other suitable silicate glasses or materials providing similar optic properties and/or insulative properties may be used in other embodiments. Chemical-mechanical polishing (CMP) may then be performed after deposition of the second layer 162, resulting in the planar surface shown in FIG. 3M.

As shown in FIG. 3N, a photoresist 164 is then deposited and patterned on the third layer 162 of the first dielectric component 104. In some embodiments, the photoresist 164 is applied to the third layer 162 of the first dielectric component 104, after which portions of the photoresist 164 are developed by exposure from a suitable light source to form a pattern thereon. The unexposed portions are then removed, resulting in the patterned photoresist 164 shown in FIG. 3N. Etching is then performed in accordance with the patterned photoresist 164, removing unprotected portions of the third layer 162 of the first dielectric component 104, and forming a third resonator cavity 166 and second resonator VIA cavities 168 in the third layer 162 of the first dielectric component 104 as shown in FIG. 3O. That is, portions of the third layer 162 of the dielectric component 104 unprotected by the aforementioned photoresist 164 are removed, resulting in the third resonator cavity 166 and the second resonator VIA cavities 168. Suitable removal processes include, for example and without limitation, an etching process implemented as a dry etching process, a RIE process, a wet etching process, some other etching process, or a combination of the foregoing.

In FIG. 3P, resonator metal glue layer 116 is shown deposited on the third layer 162 of the first dielectric component 104 and on the surfaces of the third resonator cavity 166 and the second resonator VIA cavities 168. As noted above, the resonator metal glue layer 116 may include, for example and without limitation, TiN, TaN, W, Ti, Ta, or the like, and may be implemented with a thickness in the range of about 100A to 10kA. Formation of the resonator metal glue layer 116 may be accomplished via any suitable deposition or layer processes, including, for example and without limitation, deposited by, for example, CVD, PVD, ALD, sputtering, another deposition process, or any suitable combination thereof.

A third layer 170 of resonator metal 114 is then deposited on the resonator metal glue layer 116 of the semiconductor device structure 100, filling the third resonator cavity 166 and the second resonator VIA cavities 168, as shown in FIG. 3O. In accordance with some embodiments, the resonator metal material 114 may comprise, for example and without limitation, W, Cu, Al, AICu, AISiCu, AISi, or the like, which may be formed by CVD, PVD, ALD, ECP, sputtering, another deposition process, or any suitable combination thereof. It will be appreciated that other suitable metals or metal-alloy materials providing similar conductive properties may be used in other embodiments. Thereafter, as shown in FIG. 3R, chemical-mechanical polishing (CMP) is performed on the semiconductor device structure 100 to remove portions of the third layer 170 of the resonator metal material 114 and the resonator metal glue layer 116 on the third layer 162 of the first dielectric component 104. It will be appreciated that the required resonator metal material 114 of the first resonator component (R-1) 108 has thus been formed. That is, as shown in FIG. 3R, the first resonator component (R-1) 108, the second resonator component (R-2) 110 and the third resonator component (R-3) 112 are all now formed in the first dielectric component 104.

The second dielectric component 106 is then formed on the semiconductor device structure 100, as shown in FIG. 3S. That is, one or more layers of dielectric material are deposited or formed on the first dielectric component 104, i.e., the third layer 162 of the dielectric component as well as the third layer 170 (see FIG. 3O) of resonator metal 114. The second dielectric component 106 may comprise, for example and without limitation, one or more layers of USG, SiN, PSG, BPSG, FSG, LK, ELK, BD, or the like. It will be appreciated that other suitable silicate glasses or materials providing similar optic properties and/or insulative properties may be used in other embodiments. In accordance with some embodiments, the second dielectric component 106 may be implemented with a thickness in the range of about 100A to 500kA.

A photoresist 172 is then deposited and patterned on the second dielectric component 106, as illustrated in FIG. 3T. In some embodiments, the photoresist 172 is applied to the second dielectric component 106, after which portions of the photoresist 172 are developed by exposure from a suitable light source to form a pattern thereon. The unexposed portions are then removed, resulting in the patterned photoresist 172 shown in FIG. 3T. Etching is then performed to remove those portions of the second dielectric component 106 unprotected by the aforementioned photoresist 172 to form capping metal VIA cavities 174. Suitable removal processes include, for example and without limitation, an etching process implemented as a dry etching process, a RIE process, a wet etching process, some other etching process, or a combination of the foregoing. FIG. 3U provides an illustration of a stage of fabrication of the semiconductor device structure 100 after formation of the capping metal VIA cavities 174.

In FIG. 3V, a capping metal glue layer 124 is shown deposited on the second dielectric component 106 and on the surfaces of the capping metal VIA cavities 174. As discussed above with respect to FIG. 1, the capping metal glue layer 124 may include, for example and without limitation, TiN, TaN, W, Ti, Ta, or the like, and may be implemented with a thickness in the range of about 100A to 10kA. Formation of the capping metal glue layer 124 may be accomplished via any suitable deposition or layer processes, including, for example and without limitation, deposited by, for example, CVD, PVD, ALD, sputtering, another deposition process, or any suitable combination thereof.

A capping metal layer 120 is then deposited on the capping metal glue layer 124 of the semiconductor device structure 100, filling the capping metal VIA cavities 174, thereby forming the capping metal VIAs 122A, 122B, 122C, as shown in FIG. 3W. In accordance with some embodiments, the capping metal layer 120 may comprise, for example and without limitation, AICu, AISiCu, AISi, W, ITO, Cu, or the like. It will be appreciated that other suitable metals or metal-alloy materials providing similar conductive properties may be used in other embodiments. In accordance with some embodiments, the capping metal layer 120 may be implemented with a thickness in the range of about 100A to 500kA. Extending downward from the capping metal layer 120 are a first capping metal VIA 122A contacting the first resonator component (R-1) 108, a second capping metal VIA 122B contacting the second resonator component (R-2) 110, and a third capping metal VIA 122C contacting the third resonator component (R-3) 112. It will be appreciated that the metal capping VIAs 122A-122C may comprise the same material as that of the metal capping layer 120. Thereafter, as shown in FIG. 3X, chemical-mechanical polishing (CMP) is performed on the semiconductor device structure 100 to remove portions of the capping metal layer 120.

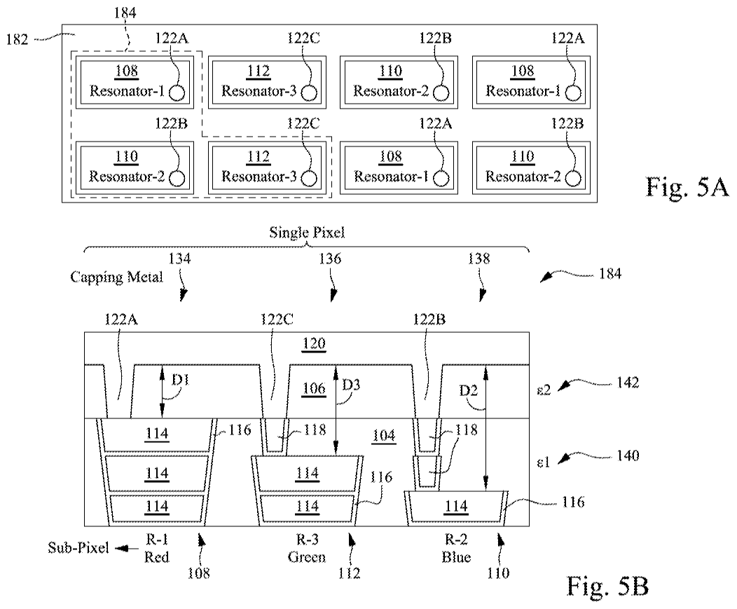

Turning now to FIGS. 4A and 4B, there show a top view of an array 180 of semiconductor device structures 100 and a cross-sectional side view of one semiconductor device structure 100 of the array 180. As briefly mentioned above, each semiconductor device structure 100 may be implemented as a pixel, with each pixel comprising a red resonator, green resonator, blue resonator. The array 180 of FIG. 4A corresponds to an array of semiconductor device structures 100, wherein each resonator 108-112 are arranged linearly, i.e., the first resonator component (R-1) 108, then the second resonator component (R-2) 110, and last the third resonator component (R-3) 112. In contrast, FIGS. 5A and 5B illustrate an alternate embodiment, wherein the arrangement of the resonators (R-1) 108, (R-2) 110, and (R-3) 112 are in a different order. Thus, the array 182 of FIG. 5A illustrates that one semiconductor device structure or pixel 184 is arranged in an “L”-shape. When viewed from the side, as shown in FIG. 5B, the order of the resonators 108-112 are shown as the first resonator (R-1) 108, the third resonator (R-3) 112 and then the second resonator (R-2) 110. It will be appreciated that the ordering of the resonators 108-112 may be altered in a variety of manners, and the illustrations of FIGS. 4A-5B are intended solely as nonlimiting examples.

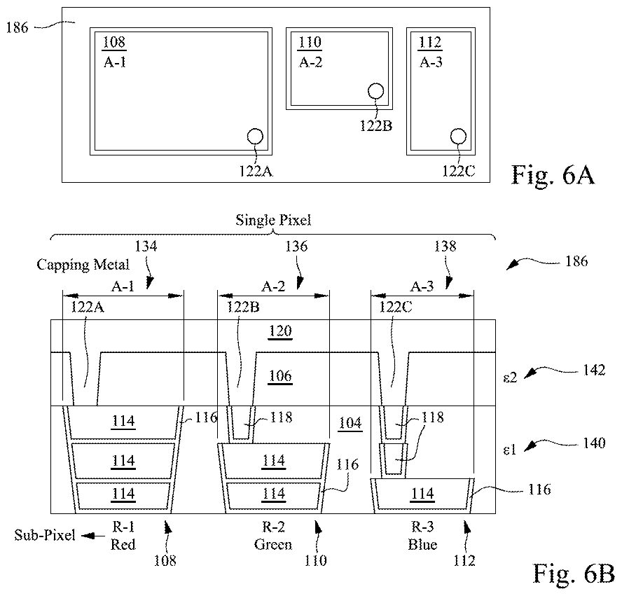

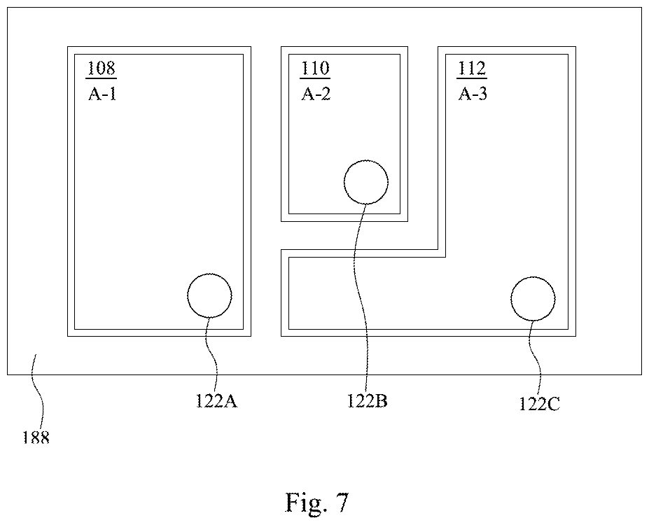

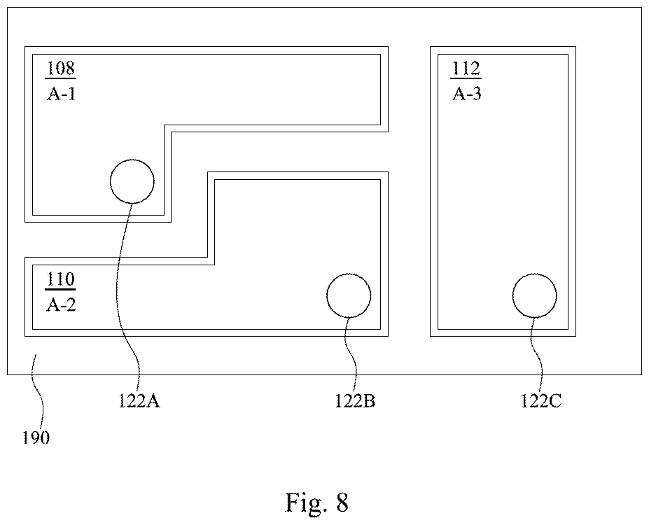

FIGS. 6A-6B provide a third embodiment of a semiconductor device structure 186, wherein the order of the resonators 108-112 remains the same as that of FIG. 1 (i.e., (R-1) 108, then (R-2) 110, and last (R-3) 112, however the area of each resonator 108-112 differs. For example, in FIG. 6A, it is illustrated that the area of the first resonator component (R-1) 108 is larger than the area of either the second resonator component (R-1) 110 and/or the third resonator component (R-3) 112. FIG. 7 provides an illustration of a top view of a fourth embodiment of a semiconductor device structure 188, wherein the areas (A-1, A-2, A-3) of each resonator 108-112 differs. Furthermore, the embodiment of FIG. 7 illustrates that the shape of each resonator 108-112, when viewed from the top, also differs. Similarly, FIG. 8 provides an illustration of a fifth embodiment of a semiconductor device structure 190, wherein the resonators 108-112 are also of different areas and shapes, differing from the shapes used in FIGS. 4A-7. The skilled artisan will appreciate that other embodiments are also capable of being implemented in with the subject disclosure.

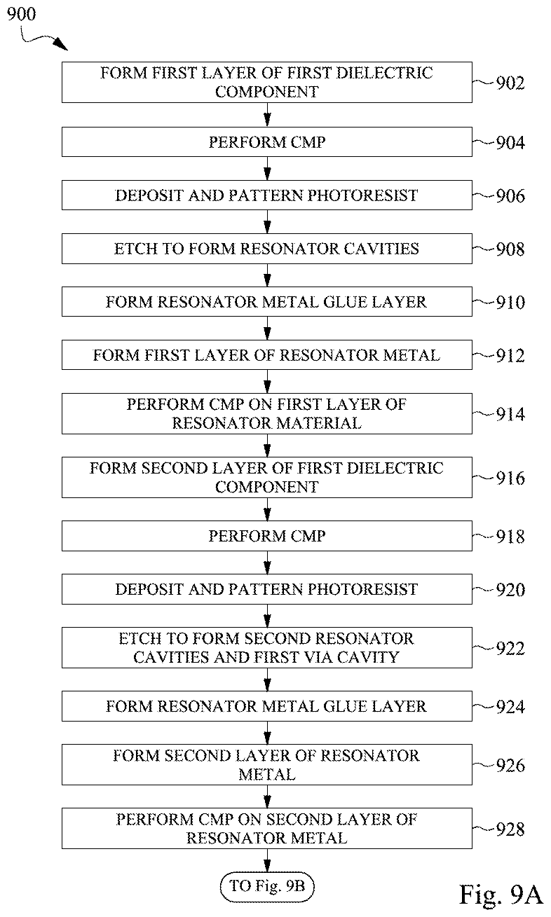

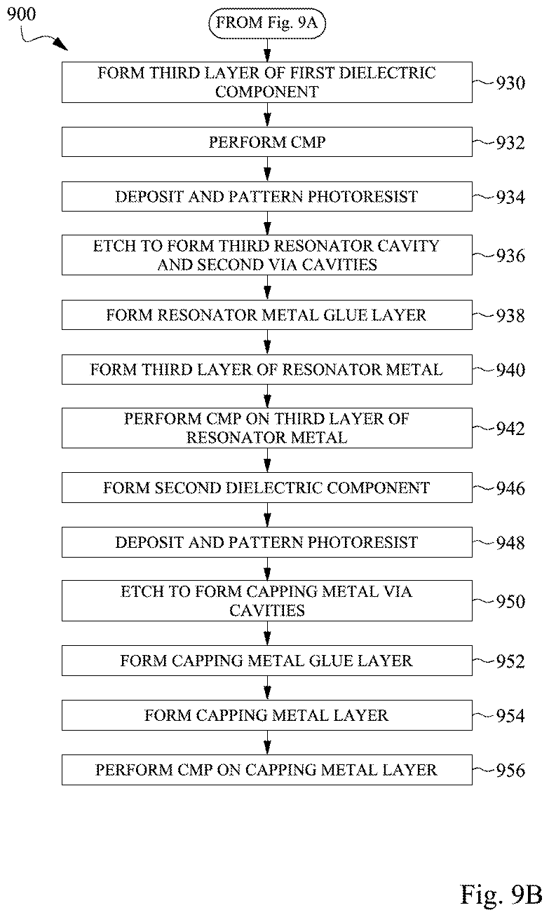

Referring now to FIGS. 9A-9B, there is shown a flowchart illustrating a method 900 for fabricating a semiconductor device structure 100 in accordance with some embodiments. The method 900 begins at step 902, whereupon a first layer 144 of a first dielectric component 104 is formed on a base structure or layer 102. FIG. 3A provides an illustrative view of this stage of fabrication of the semiconductor device structure. As discussed above, the first dielectric component 104, and as such, the first layer 144, may be implemented as, for example and without limitation, USG, SiN, PSG, BPSG, FSG, LK, ELK, BD, or other suitable silicate glasses or materials providing similar optic properties and/or insulative properties. It will be appreciated that such formation r deposition of the first layer 144 may be performed via CVD, PVD, ALD, sputtering, etc. At step 902, chemical-mechanical polishing (CMP) may be performed after deposition of the first layer 144, resulting in the planar surface discussed above with respect to FIG. 3A.

A photoresist 146 is then deposited and patterned on the first layer 144 of the first dielectric component 104 at step 906. That is, a layer of photoresist 146 is deposited on the first layer 144, after which portions of the photoresist 146 are developed by exposure from a suitable light source to form a pattern thereon. The unexposed portions are then removed, resulting in the patterned photoresist 146 shown in FIG. 3B. At step 908, etching is performed in accordance with the patterned photoresist 146 to form resonator cavities 148 in the first layer 144 of the first dielectric component 104. That is, portions of the first layer 144 of the dielectric component 104 unprotected by the aforementioned photoresist 146 are removed, resulting in the resonator cavities 148 as illustrated in FIG. 3C. Suitable removal processes include, for example and without limitation, an etching process implemented as a dry etching process, a RIE process, a wet etching process, some other etching process, or a combination of the foregoing.

At step 910, a resonator metal glue layer 116 is formed or deposited on the first layer 144 of the first dielectric component 104 and on the surfaces of the resonator cavities 148. As discussed above, the resonator metal glue layer 116 may include, for example and without limitation, TiN, TaN, W, Ti, Ta, or the like. Such formation or deposition may be performed by any suitable deposition or layer processes, e.g., CVD, PVD, ALD, ECP, etc. FIG. 3D provides an illustrative example of the formation of the resonator glue metal layer 116 on the above-identified surfaces. A first layer 150 of resonator metal 114 is then deposited or formed at step 912 on the resonator metal glue layer 116, filling the resonator cavities 148, as illustrated in FIG. 3E. In accordance with some embodiments, the resonator metal material 114 may comprise, for example and without limitation, W, Cu, Al, AICu, AISiCu, AISi, or other suitable metals or metal-alloy materials providing similar conductive properties. Suitable formation methods used at step 912 may include, for example and without limitation, CVD, PVD, ALD, sputtering, ECP, etc. Chemical-mechanical polishing (CMP) is then performed on the semiconductor device structure 100 at step 914 to remove portions of the first layer 150 of the resonator metal material 114 and the resonator metal glue layer 116, as shown in FIG. 3F. It will be appreciated that the required resonator metal material 114 of the third resonator component (R-3) 112 has thus been formed, while additional resonator metal material 114 remains to be formed for the remaining resonator components (R-1) 108 and (R-2) 110. That is, as shown in FIG. 3F, the third resonator component (R-3) 112 is now formed in the first dielectric component 104.

A second layer 152 of the first dielectric component 104 is then formed on first layer 144 and the remaining first layer 150 of the resonator metal material 114 at step 916. In accordance with some embodiments, the second layer 152 may be implemented as the same material as that of the first layer 144, e.g., USG, SiN, PSG, BPSG, FSG, LK, ELK, BD, or other suitable silicate glasses or materials providing similar optic properties and/or insulative properties. Formation of the second layer 152 of the first dielectric component 104 may be accomplished via any suitable deposition or layer processes, including, for example and without limitation, CVD, PVD, ALD, sputtering, etc. Chemical-mechanical polishing (CMP) is then performed at step 918 on the second layer 152, resulting in the planar surface shown in FIG. 3G.

At step 920, a photoresist 154 is then deposited and patterned on the second layer 152 of the first dielectric component 104. FIG. 3H provides an illustrative view of the patterning of the photoresist 154. That is, the photoresist 154 is applied to the second layer 152 of the first dielectric component 104, after which portions of the photoresist 154 are developed by exposure from a suitable light source to form a pattern. Any unexposed portions of the photoresist 154 are then removed. At step 922, etching is performed on the second layer 152 of the first dielectric component 104 based upon the patterned photoresist 154. As such, any unprotected portions of the second layer 152 of the first dielectric component 104 are removed to form second resonator cavities 156 and a first resonator VIA cavity 158, as shown in FIG. 3I. As discussed above, suitable removal processes include, for example and without limitation, a dry etching process, a RIE process, a wet etching process, some other etching process, or a combination of the foregoing.

At step 924, resonator metal glue layer 116 (e.g., TiN, TaN, W, Ti, Ta, etc.) is then deposited on the second layer 152 of the first dielectric component 104 and on the surfaces of the second resonator cavities 156 and the first resonator VIA cavity 158. FIG. 3J provides an illustration of the formation (e.g., CVD, PVD, ALD, sputtering, etc.) of the resonator metal glue layer 116. A second layer 160 of resonator metal 114 is then formed at step 926 on the resonator metal glue layer 116 of the semiconductor device structure 100, filling the second resonator cavities 156 and the first resonator VIA cavity 158. FIG. 3K provides an illustrative example of the deposition of the second layer 160 of resonator metal 114 on the semiconductor device 100. In accordance with some embodiments, the resonator metal material 114 may comprise, for example and without limitation, W, Cu, Al, AICu, AISiCu, AISi, or the like, which may be formed by CVD, PVD, ALD, ECP, sputtering, another deposition process, or any suitable combination thereof. It will be appreciated that other suitable metals or metal-alloy materials providing similar conductive properties may be used in other embodiments.

At step 928, chemical-mechanical polishing (CMP) is performed on the semiconductor device structure 100 to remove portions of the second layer 160 of the resonator metal material 114 and the resonator metal glue layer 116. FIG. 3L provides an illustration of the semiconductor device structure 100 after the aforementioned CMP of step 928. It will be appreciated that the required resonator metal material 114 of the second resonator component (R-2) 110 has thus been formed, while additional resonator metal material 114 remains to be formed for the remaining resonator component (R-1) 108. That is, as shown in FIG. 3L, the second resonator component (R-2) 110 and the third resonator component (R-3) 112 are now formed in the first dielectric component 104.

A third layer 162 of the first dielectric component 104 is then formed on second layer 152 of the first dielectric component 104 and the remaining second layer 160 of the resonator metal material 114, at step 930. As shown in FIG. 3M., and discussed in detail above, the third layer 162 may be formed by CVD, PVD, ALD, sputtering, etc., of suitable material, e.g., USG, SiN, PSG, BPSG, FSG, LK, ELK, BD, or the like. Chemical-mechanical polishing (CMP) may then be performed at step 932 after deposition of the second layer 162, resulting in the planar surface shown in FIG. 3M.

At step 934, a photoresist 164 is deposited and patterned on the third layer 162 of the first dielectric component 104. Application and development of the photoresist 164 is explained in greater detail above with respect to FIG. 3N. At step 936, etching is performed in accordance with the patterned photoresist 164, removing unprotected portions of the third layer 162 of the first dielectric component 104, and forming a third resonator cavity 166 and second resonator VIA cavities 168 in the third layer 162 of the first dielectric component 104 as shown in FIG. 3O. Thereafter, at step 938, a resonator metal glue layer 116 is formed on the third layer 162 of the first dielectric component 104 and on the surfaces of the third resonator cavity 166 and the second resonator VIA cavities 168. FIG. 3P provides an illustrative example of this stage of fabrication of the semiconductor device structure 100. As noted above, the resonator metal glue layer 116 may include, for example and without limitation, TiN, TaN, W, Ti, Ta, etc., and such formation may be accomplished via any suitable deposition or layer processes, including, for example and without limitation, deposited by, for example, CVD, PVD, ALD, sputtering, another deposition process, or any suitable combination thereof.

A third layer 170 of resonator metal 114 is then deposited at step 940 on the resonator metal glue layer 116 of the semiconductor device structure 100, filling the third resonator cavity 166 and the first resonator VIA cavities 168, as shown in FIG. 3O. At step 942, chemical-mechanical polishing (CMP) is performed on the semiconductor device structure 100 to remove portions of the third layer 170 of the resonator metal material 114 and the resonator metal glue layer 116 on the third layer 162 of the first dielectric component 104., as illustrated in FIG. 3R. It will be appreciated that the required resonator metal material 114 of the first resonator component (R-1) 108 has thus been formed. That is, as shown in FIG. 3R, the first resonator component (R-1) 108, second resonator component (R-2) 110, and the third resonator component (R-3) 112 are now formed in the first dielectric component 104.

At step 946, a second dielectric component 106 is formed on the semiconductor device structure 100, as illustrated in FIG. 3S. That is, one or more layers of dielectric material are deposited or formed on the first dielectric component 104, i.e., the third layer 162 of the dielectric component as well as the third layer 170 of resonator metal 114. As indicated above, the second dielectric component 106 may be implemented as, for example and without limitation, one or more layers of USG, SiN, PSG, BPSG, FSG, LK, ELK, BD, or the like. It will be appreciated that other suitable silicate glasses or materials providing similar optic properties and/or insulative properties may be used in other embodiments. In accordance with some embodiments, the second dielectric component 106 may be implemented with a thickness in the range of about 100A to 500kA.

At step 948, a photoresist 172 is deposited and patterned on the second dielectric component 106. As illustrated in FIG. 3T, the photoresist 172 is applied to the second dielectric component 106, after which portions of the photoresist 172 are developed by exposure from a suitable light source to form a pattern thereon. The unexposed portions are then removed, leaving the illustrated patterned photoresist 172. Etching, e.g., a dry etching process, a RIE process, a wet etching process, is then performed at step 950 to remove those portions of the second dielectric component 106 unprotected by the aforementioned photoresist 172 to form capping metal VIA cavities 174. FIG. 3U provides an illustration of a stage of fabrication of the semiconductor device structure 100 after formation of the capping metal VIA cavities 174 at step 950.

At step 952, a capping metal glue layer 124 is shown formed on the second dielectric component 106 and on the surfaces of the capping metal VIA cavities 174. As discussed above with respect to FIG. 3V, the capping metal glue layer 124 may include, for example and without limitation, TiN, TaN, W, Ti, Ta, etc., and be formed via any suitable deposition or layer processes, including, e.g., CVD, PVD, ALD, sputtering, and the like.

At step 954, a capping metal layer 120 is then formed on the capping metal glue layer 124, filling the capping metal VIA cavities 174, thereby forming the capping metal VIAs 122A, 122B, 122C, as shown in FIG. 3W. As discussed above, the capping metal layer 120 may comprise, for example and without limitation, AICu, AISiCu, AISi, W, ITO, Cu, or other suitable metals or metal-alloy materials providing similar conductive properties, and may be formed via any suitable mechanism, e.g., CVD, PVD, ALD, sputtering, ECP, etc. Extending downward from the capping metal layer 120 are a first capping metal VIA 122A contacting the first resonator component (R-1) 108, a second capping metal VIA 122B contacting the second resonator component (R-2) 110, and a third capping metal VIA 122C contacting the third resonator component (R-3) 112. Thereafter, at step 956, chemical-mechanical polishing (CMP) is performed on the semiconductor device structure 100 to remove portions of the capping metal layer 120, resulting in the semiconductor device structure depicted in FIG. 3X.

As referenced above, various embodiments may be utilized in the fabrication of pixels for displays, e.g., LEDs. Traditional OLED have subpixels or resonators that are not positioned on the same plane, as light path dictates color output. This lack of planarity can easily cause upper layer process weakness (film DEP uniformity/ETC uniformity/film adhesion/interface stress/CMP down force uniformity/topography effect, etc.). In contrast, the subject embodiments utilize a single plane for the resonators, thereby alleviating the aforementioned weakness.

In accordance with a first embodiment, there is provided a method for fabricating a semiconductor device structure that includes forming a first resonator cavity wall metal component through a first layer, a second layer and a third layer of a first dielectric component, the first resonator cavity wall component length equal to the total thickness of the first layer, the second layer and the third layer of the first dielectric component; forming a second resonator cavity wall metal component through the first layer and the second layer of the first dielectric component, the second resonator cavity wall component length equal to the total thickness of the first layer and the second layer of the first dielectric component; forming a third resonator cavity wall metal component through the third layer of the first dielectric component, the third resonator cavity wall component length equal to the total thickness of the first layer dielectric component; forming a second dielectric component on the first dielectric component; forming capping metal VIAs through the second dielectric component to each of the first resonator cavity wall metal component, the second resonator cavity wall metal component, and the third resonator cavity wall metal component; and forming a planer capping metal layer on the second dielectric component, the capping metal layer contacting the first resonator cavity wall metal component, the second resonator cavity wall metal component, and the third resonator cavity wall metal component through the respective capping metal VIAs, wherein a first resonator cavity within the second dielectric component extends a first cavity length from the planer capping metal layer to the first resonator cavity wall metal component, a second resonator cavity within the first and second dielectric components extends a second cavity length from the planer capping metal layer to the second resonator cavity wall metal component, and a third resonator cavity within the second dielectric component extends a second cavity length from the planer capping metal layer to the third resonator cavity wall metal component.

In accordance with a second embodiment, there is provided a semiconductor device structure that includes a first dielectric component; a plurality of resonator cavity wall metal components disposed in the first dielectric component, each of the plurality of resonator cavity wall metal components associated with a distinct resonator cavity extending into the first dielectric component, and each of the resonator cavities have a different cavity length extending into the first dielectric component; a second dielectric component positioned on the first dielectric component; and a planer capping metal layer disposed on the second dielectric component, the planer capping metal layer including at least one capping metal VIA extending through the second dielectric component to the plurality of resonator cavity wall metal components.

In accordance with a third embodiment, there is provided a method of fabricating a semiconductor device structure that includes forming a first portion of first resonator cavity wall component and a second resonator cavity wall component in a first layer of a first dielectric component; forming a second layer of the first dielectric component on the first layer thereof; forming a second portion of the first resonator cavity wall component in the second layer of the first dielectric component; forming a second dielectric component on the first dielectric component; forming at least one capping metal VIA through the second dielectric component to at least one of the first resonator cavity wall component, or the second resonator cavity wall component; forming a planer capping metal layer on the second dielectric component, the capping metal layer contacting at least one of the first resonator cavity wall component, or the second resonator cavity wall component through the at least one capping metal VIA, wherein a first resonator cavity within the second dielectric component extends a first cavity length from the planer capping metal layer to the first resonator cavity wall metal component, and a second resonator cavity within the first and second dielectric components extends a second cavity length from the planer capping metal layer to the second resonator cavity wall metal component.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device structure, comprising:
forming a first resonator cavity wall metal component through a first layer, a second layer and a third layer of a first dielectric component, the first resonator cavity wall component length equal to the total thickness of the first layer, the second layer and the third layer of the first dielectric component;
forming a second resonator cavity wall metal component through the first layer and the second layer of the first dielectric component, the second resonator cavity wall component length equal to the total thickness of the first layer and the second layer of the first dielectric component;
forming a third resonator cavity wall metal component through the third layer of the first dielectric component, the third resonator cavity wall component length equal to the total thickness of the first layer dielectric component;
forming a second dielectric component on the first dielectric component;
forming capping metal VIAs through the second dielectric component to each of the first resonator cavity wall metal component, the second resonator cavity wall metal component, and the third resonator cavity wall metal component; and
forming a planer capping metal layer on the second dielectric component, the capping metal layer contacting the first resonator cavity wall metal component, the second resonator cavity wall metal component, and the third resonator cavity wall metal component through the respective capping metal VIAs,
wherein a first resonator cavity within the second dielectric component extends a first cavity length from the planer capping metal layer to the first resonator cavity wall metal component, a second resonator cavity within the first and second dielectric components extends a second cavity length from the planer capping metal layer to the second resonator cavity wall metal component, and a third resonator cavity within the second dielectric component extends a second cavity length from the planer capping metal layer to the third resonator cavity wall metal component.

2. The method of claim 1, wherein forming the first resonator cavity wall metal component, the second resonator cavity wall metal component and the third resonator cavity wall metal component further comprises:
depositing a layer of photoresist on the first layer of the first dielectric component;
patterning the deposited photoresist on the first layer of the first dielectric component;
etching the first layer of the first dielectric component in accordance with the patterned photoresist;
forming a resonator metal glue layer on the first layer of the first dielectric component;
forming a first layer of resonator metal on the resonator metal glue layer; and
performing chemical-mechanical polishing on the first layer of resonator metal to form a first portion of the first resonator cavity wall metal component, a first portion of the second resonator cavity wall metal component, and the third resonator cavity wall metal component.

3. The method of claim 2, wherein forming the first and second resonator cavity wall metal components further comprises:
forming the second layer of the first dielectric component on the first layer of the first dielectric component, the first portion of the first resonator cavity wall metal component, the first portion of the second resonator cavity wall metal component and the third resonator cavity wall component;
patterning a photoresist on the second layer of the first dielectric component;
etching the second layer of the first dielectric component in accordance with the patterned photoresist;
forming a resonator metal glue layer on the second layer of the first dielectric component and the first layer of resonator metal;
forming a second layer of resonator metal on the resonator metal glue layer; and
performing chemical-mechanical polishing on the second layer of resonator metal to form a second portion of the first resonator cavity wall metal component and a second portion of the second resonator cavity wall metal component, the second resonator cavity wall metal component completing the second resonator cavity wall metal component.

4. The method of claim 3, wherein forming the third resonator cavity wall metal component further comprises:
forming the third layer of the first dielectric component on the second layer of the first dielectric component, the second portion of the first cavity wall metal component and the second resonator cavity wall metal component;
patterning a photoresist on the third layer of the first dielectric component;
etching the third layer of the first dielectric component in accordance with the patterned photoresist;
forming a resonator metal glue layer on the third layer of the first dielectric component and the second portion of the first cavity wall component;
forming a third layer of resonator metal on the resonator metal glue layer; and
performing chemical-mechanical polishing on the third layer of resonator metal to form a third portion of the first resonator cavity wall metal component, the third resonator cavity wall metal component completing the first resonator cavity wall metal component.

5. The method of claim 1, wherein the first resonator cavity, the second resonator cavity and the third resonator cavity are formed in an array fabricated on the semiconductor structure, and each of the capping metal VIAs includes an external electrical connection point.

6. The method of claim 1, wherein the first resonator cavity is formed to include a cross-sectional area width of A-1, the second resonator cavity is formed to include a cross-sectional area width of A-2 different from A-1, and the third resonator cavity is formed to include a cross-sectional area width of A-3 different from A-1 and A-2.

7. The method of claim 1, wherein the first cavity length is less than the second cavity length, and the second cavity length is less than the first cavity length.

8. A semiconductor device structure, comprising:
a first dielectric component;
a plurality of resonator cavity wall metal components disposed in the first dielectric component, each of the plurality of resonator cavity wall metal components associated with a distinct resonator cavity extending into the first dielectric component, and each of the resonator cavities have a different cavity length extending into the first dielectric component;
a second dielectric component positioned on the first dielectric component; and
a planer capping metal layer disposed on the second dielectric component, the planer capping metal layer including at least one capping metal VIA extending through the second dielectric component to the plurality of resonator cavity wall metal components.

9. The semiconductor device structure of claim 8, wherein the first dielectric component further comprises:
a first layer having a first portion of a first resonator cavity wall metal component, a first portion of a second resonator cavity wall metal component, and a third resonator cavity wall metal component;
a second layer having a second portion of the first resonator cavity wall metal component and a second portion of the second resonator cavity wall metal component, the second resonator cavity wall metal component completing the second resonator cavity wall metal component; and
a third layer having a third portion of the first resonator cavity wall metal component, the third resonator cavity wall metal component completing the first resonator cavity wall metal component.

10. The semiconductor device structure of claim 9, wherein a first resonator cavity within the second dielectric component extends a first cavity length from the planer capping metal layer to the first resonator cavity wall metal component, a second resonator cavity within the first and second dielectric components extends a second cavity length from the planer capping metal layer to the second resonator cavity wall metal component, and a third resonator cavity within the second dielectric component extends a second cavity length from the planer capping metal layer to the third resonator cavity wall metal component.

11. The semiconductor device structure of claim 9, further comprising:
a resonator metal glue layer disposed between the first dielectric component first layer and the second portion of the first resonator cavity wall metal component, and disposed between the first dielectric component layer and the second portion of the second resonator cavity wall metal component; and
a resonator metal glue layer disposed between the first dielectric component second layer and the third portion of the first resonator cavity wall metal component.

12. The semiconductor device structure of claim 8, wherein the distinct resonator cavities include a first resonator cavity, a second resonator cavity and a third resonator cavity formed in an array fabricated on the semiconductor structure, and each of the capping metal VIAs includes an external electrical connection point.

13. The semiconductor device structure of claim 12, wherein the first resonator cavity is formed to include a cross-sectional area width of A-1, the second resonator cavity is formed to include a cross-sectional area width of A-2 different from A-1, and the third resonator cavity is formed to include a cross-sectional area width of A-3 different from A-1 and A-2.

14. The semiconductor device structure of claim 9, wherein the second resonator cavity wall metal component is disposed in the first and second layers of the dielectric component.

15. The semiconductor device structure of claim 9, wherein the third resonator cavity wall metal component is disposed in the first layer of the dielectric component.

16. The semiconductor device structure of claim 9, further comprising at least one resonator VIA disposed in the first dielectric component between at least one of the plurality of resonator cavity wall metal components and the second dielectric component.

17. The semiconductor device structure of claim 12, further comprising a glue layer disposed between the at least one resonator VIA and at least one layer of the first dielectric component.

18. A method of fabricating a semiconductor device, comprising:
forming a first portion of first resonator cavity wall component and a second resonator cavity wall component in a first layer of a first dielectric component;
forming a second layer of the first dielectric component on the first layer thereof;
forming a second portion of the first resonator cavity wall component in the second layer of the first dielectric component;
forming a second dielectric component on the first dielectric component;
forming at least one capping metal VIA through the second dielectric component to at least one of the first resonator cavity wall component, or the second resonator cavity wall component;
forming a planer capping metal layer on the second dielectric component, the capping metal layer contacting at least one of the first resonator cavity wall component, or the second resonator cavity wall component through the at least one capping metal VIA,
wherein a first resonator cavity within the second dielectric component extends a first cavity length from the planer capping metal layer to the first resonator cavity wall metal component, and a second resonator cavity within the first and second dielectric components extends a second cavity length from the planer capping metal layer to the second resonator cavity wall metal component.

19. The method of claim 18, further comprising forming at least one resonator VIA on at least one of the first resonator cavity wall component or the second resonator cavity wall component.

20. The method of claim 18, wherein the first cavity length is less than the second cavity length.
